(19) United States
(12) Patent Application Publication
(10) Pub. No.: US 2024/0321896 A1
(43) Pub. Date: Sep. 26, 2024

(54) DISPLAY PANEL AND DISPLAY DEVICE

(71) Applicant: Tianma Advanced Display Technology Institute (Xiamen) Co.,Ltd., Xiamen (CN)

(72) Inventors: Rusheng LIU, Xiamen (CN); Cao LIU, Xiamen (CN); Zhenyu JIA, Xiamen (CN); Yukun HUANG, Xiamen (CN)

(21) Appl. No.: 18/736,521

(22) Filed: Jun. 6, 2024

(30) Foreign Application Priority Data
Oct. 30, 2023 (CN) 202311424528.7

(51) Int. Cl. H01L 27/12; H01L 33/62

(52) U.S. Cl. CPC H01L 27/1218; H01L 27/124; H01L 33/62

(57) ABSTRACT

A display panel and a display device, the display panel includes: a driving backplane, including a substrate and an array layer located on a side of the substrate; a light emitting diode located on a side of the driving backplane; the array layer includes an organic layer, the organic layer includes an organic sublayer, and the organic sublayer is provided with an inorganic layer on a side of the organic sublayer away from the substrate.

### CROSS-REFERENCE TO RELATED DISCLOSURE

The present disclosure claims priority to Chinese Patent Application No. 202311424528.7, filed on Oct. 30, 2023, the content of which is incorporated herein by reference in its entirety.

### TECHNICAL FIELD

The present disclosure relates to the technical field of display, and in particularly, to a display panel and a display device.

### BACKGROUND

Light emitting diode (LED) display panels are widely used in various display fields due to their excellent characteristics such as high brightness, high resolution, high response speed, and low power consumption. However, the existing LED display panel has poor water and oxygen resistance and is prone to display abnormality caused by water and oxygen erosion.

### SUMMARY

In view of this, embodiments of the present disclosure provide a display panel and a display device for improving water and oxygen resistance of the display panel.

In a first aspect of the present disclosure, a display panel is provided.
a driving backplane, comprising a substrate and an array layer located on a side of the substrate;
a light emitting diode located on a side of the driving backplane, particularly, on a side of the array layer away from the substrate;

The array layer comprises an organic layer, the organic layer comprises an organic sublayer, and the organic sublayer is provided with an inorganic layer on a side of the organic sublayer away from the substrate.

In another aspect, the present disclosure provides a display device including the display panel described above.

One of the technical solutions described above has following beneficial effects.

Compared with organic materials, inorganic materials have better ability to block water and oxygen. In the embodiment of the present disclosure, by adding the inorganic layer above the organic sublayer of the array layer, the water and oxygen transmission path between the organic encapsulation layer and the organic sublayer can be cut off by using the inorganic layer, and water and oxygen are blocked from further permeating into the driving backplane in the vertical direction (perpendicular to the plane of the substrate), thereby effectively improving the water and oxygen block ability of the driving backplane, weakening the influence of water and oxygen on devices such as transistors in the array layer, and improving the display reliability of the screen.

In addition, it should also be noted that, compared with providing the inorganic encapsulation layer above the organic encapsulation layer, the embodiment of the present disclosure selects providing the inorganic layer above the organic sublayer in the array layer, which can protect devices such as transistors to a greater extent. Specifically, if an inorganic encapsulation layer is selected to be provided above the organic encapsulation layer, the inorganic encapsulation layer cannot cut off a water and oxygen transmission path between the organic encapsulation layer and the array layer, so that water and oxygen permeating into the organic encapsulation layer or permeating into the organic encapsulation layer through the side surface of the display panel in the manufacturing process cannot be blocked, and this part of water and oxygen can still further permeate into the array layer to affect devices such as transistors. The inorganic layer in the embodiments of the present disclosure is spaced between the organic encapsulation layer and the organic sublayer, and no matter water and oxygen permeating into the organic encapsulation layer during the manufacturing process, or water and oxygen permeating into the organic encapsulation layer through the side surface of the display panel, will be blocked by the inorganic layer, and cannot further permeate into the array layer.

### BRIEF DESCRIPTION OF DRAWINGS

In order to explain technical schemes of the embodiments of the present disclosure more clearly, the drawings used in the embodiments will be briefly introduced below.

FIG. 1 is a schematic structural diagram of a display panel according to an embodiment of the present disclosure;

FIG. 2 is another schematic structural diagram of a display panel according to an embodiment of the present disclosure;

FIG. 3 is another schematic structural diagram of a display panel according to an embodiment of the present disclosure;

FIG. 4 is another schematic structural diagram of a display panel according to an embodiment of the present disclosure;

FIG. 5 is another schematic structural diagram of a display panel according to an embodiment of the present disclosure;

FIG. 6 is a schematic structural diagram of a groove according to an embodiment of the present disclosure;

FIG. 7 is another schematic structural diagram of a groove according to an embodiment of the present disclosure;

FIG. 8 is another schematic structural diagram of a groove according to an embodiment of the present disclosure;

FIG. 9 is another schematic structural diagram of a groove according to an embodiment of the present disclosure;

FIG. 10 is a top view of a display panel according to an embodiment of the present disclosure;

FIG. 11 is another top view of a display panel according to an embodiment of the present disclosure;

FIG. 12 is another top view of a display panel according to an embodiment of the present disclosure;

FIG. 13 is another schematic structural diagram of a display panel according to an embodiment of the present disclosure;

FIG. 14 is another schematic structural diagram of a display panel according to an embodiment of the present disclosure;

FIG. 15 is another schematic structural diagram of a display panel according to an embodiment of the present disclosure;

FIG. 16 is a schematic structural diagram of a display device according to an embodiment of the present disclosure.

### DESCRIPTION OF EMBODIMENTS

In order to better understand the technical solution of the present disclosure, embodiments of the present disclosure are described in detail below with reference to the accompanying drawings.

It is to be made clear that the described embodiments are only some rather than all of the embodiments of the present disclosure. All other embodiments obtained by those of ordinary skill in the art based on the embodiments in the present disclosure without creative efforts fall within the protection scope of the present disclosure.

The terms used in the embodiments of the present disclosure are merely for the purpose of describing specific embodiments, but not intended to limit the present disclosure. The singular forms of “a”, “an” and “the” used in the embodiments of the present disclosure and the appended claims are also intended to indicate plural forms, unless clearly indicating others.

It should be understood that the term “and/or” used in the present disclosure represents an association relationship to describe associated objects, and can indicate three relationships, for example, A and/or B can indicate A alone, A and B, and B alone. In addition, the character “/” herein generally indicates an “or” relationship between the associated objects.

Unlike organic light emitting diode (OLED) display panels that use a stack of film layers to form an OLED device, LED display panels bond LED chips directly to the driving backplane. Since the height of the LED chip is large, a thicker organic encapsulation layer is generally used subsequently to encapsulate the LED chip.

However, the applicants have found in the research process that the water and oxygen resistance of the organic encapsulation material is poor, although the light-emitting layer of the LED chip is formed of an inorganic material and is less affected by water and oxygen, if the water and oxygen further permeate into the interior of the driving backplane, devices such as transistors in the driving backplane may be eroded, resulting in functional failure of the devices. It is verified that when the LED display panel of this type is subjected to the burn-in dynamic test under the conditions of the temperature of 85° C. and the relative humidity of 85%, it is very prone to display abnormality.

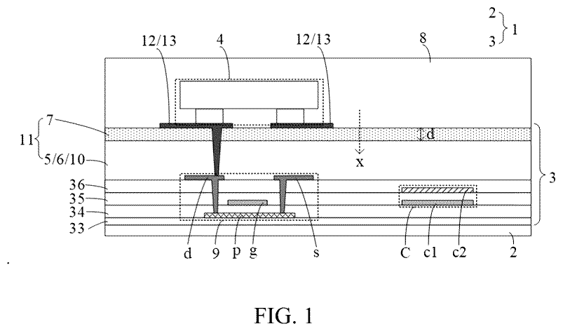

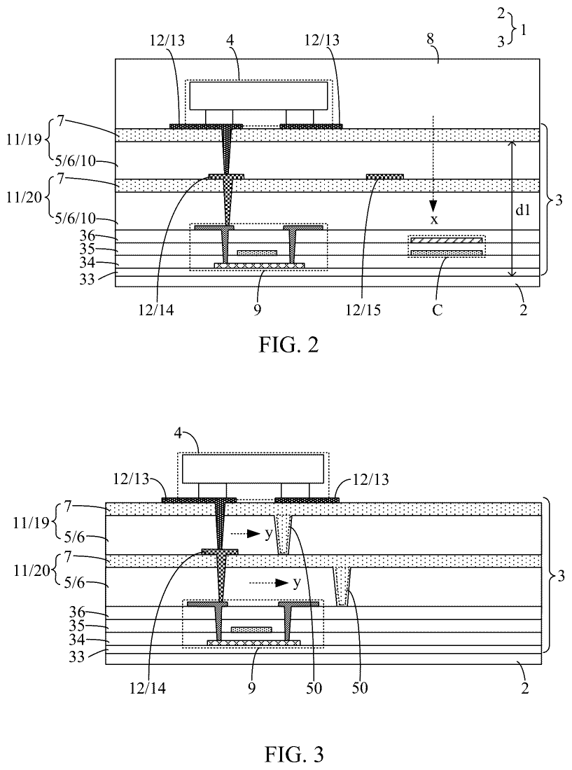

In this regard, an embodiment of the present disclosure provides a display panel, as shown in FIG. 1 and FIG. 2, FIG. 1 is a schematic structural diagram of a display panel according to an embodiment of the present disclosure, and FIG. 2 is another schematic structural diagram of a display panel according to an embodiment of the present disclosure. The display panel further includes a light emitting diode 4 located on a side of the driving backplane 1, and the light emitting diode 4 may be a micro LED.

The array layer 3 includes an organic layer 5, the organic layer 5 includes an organic sublayer 6, and the organic sublayer 6 is provided with an inorganic layer 7 on a side away from the substrate 2. Exemplarily, referring to FIG. 1, the array layer 3 may include one organic sublayer 6, or referring to FIG. 2, the array layer 3 may also include at least two organic layers 6.

Compared with organic materials, inorganic materials have better ability to block water and oxygen. In the embodiment of the present disclosure, by adding the inorganic layer 7 above the organic sublayer 6 of the array layer 3, the water and oxygen transmission path between the organic encapsulation layer 8 and the organic sublayer 6 can be cut off by using the inorganic layer 7, and water and oxygen are blocked from further permeating into the driving backplane 1 in the vertical direction x (perpendicular to the plane where the substrate 2 is located), thereby effectively improving the water and oxygen block ability of the driving backplane 1, weakening the influence of water and oxygen on devices such as transistors 9 in the array layer 3, and improving the display reliability of the screen.

In addition, it should also be noted that, compared with that the inorganic encapsulation layer is provided on the organic encapsulation layer 8, in the embodiment of the present disclosure, the inorganic protection layer 7 is provided on the organic sublayer 6 in the array layer 3, so that devices such as the transistor 9 may be protected to a greater extent. Specifically, if an inorganic encapsulation layer is selected to be provided above the organic encapsulation layer 8, the inorganic encapsulation layer cannot cut off a water and oxygen transmission path between the organic encapsulation layer 8 and the array layer 3, so that water and oxygen permeating into the organic encapsulation layer 8 or permeating into the organic encapsulation layer 8 through the side surface of the display panel in the manufacturing process cannot be blocked, and this part of water and oxygen can still further permeate into the array layer 3 to affect devices such as transistors 9 The inorganic layer 7 in the embodiments of the present disclosure is spaced between the organic encapsulation layer 8 and the organic sublayer 6, and no matter water and oxygen permeating into the organic encapsulation layer 8 during the manufacturing process, or water and oxygen permeating into the organic encapsulation layer 8 through the side surface of the display panel, will be blocked by the inorganic layer 7, and cannot further permeate into the array layer 3.

In a feasible implementation, referring to FIG. 1 and FIG. 2 again, the array layer 3 includes a transistor 9, and the transistor 9 may include an active layer p, a grid electrode g, a first electrode s, and a second electrode d. The organic sublayer 6 is located on a side of the transistor 9 away from the substrate 2, that is, the inorganic layer 7 is located on a side of the transistor 9 away from the substrate 2, and the inorganic layer 7 can block water and oxygen right above the transistor 9, providing effective protection for the transistor 9.

Optionally, the array layer 3 may further include structures such as a grid electrode insulating layer and an interlayer insulating layer. Exemplarily, referring to FIG. 1, the array layer 3 further includes a buffer layer 33, a grid electrode insulating layer 34, a first interlayer dielectric layer 35, and a second interlayer dielectric layer 36. The buffer layer 33 is located between the active layer p of the transistor 9 and the substrate 2, the grid electrode insulating layer 34 is located between the active layer p of the transistor 9 and the grid electrode g (the first pole plate cl of the capacitor C), the first interlayer dielectric layer 35 is located between the grid electrode g of the transistor 9 and the second pole plate c2 of the capacitor C, and the second interlayer dielectric layer 36 is located between the second pole plate c2 of the capacitor C and the first electrode s and the second electrode d of the transistor 9. Further, the buffer layer 33, the grid electrode insulating layer 34, the first interlayer dielectric layer 35 and the second interlayer dielectric layer 36 may all be inorganic insulating layers, and the organic sublayer 6 is located on a side of the inorganic insulating layers away from the substrate 2.

Further, referring to FIG. 1 and FIG. 2 again, the organic sublayer 6 is a planarization layer 10, that is, it may also be understood that the inorganic layer 7 is located on a side of the original planarization layer 10 in the array layer 3 away from the substrate 2.

In a feasible implementation, referring to FIG. 1 and FIG. 2 again, the array layer 3 includes at least one combined film layer 11, the combined film layer 11 includes an organic sublayer 6 and an inorganic layer 7 adjacent to each other, and the inorganic layer 7 in the combined film layer 11 is located on a side of the organic sublayer 6 away from the substrate 2. At least the sides of a part of the combined film layer 11 away from the substrate 2 are further provided with a first metal layer 12.

Exemplarily, referring to FIG. 1, the array layer 3 includes a combined film layer 11, and in this case, the first metal layer 12 may include a bonding electrode 13, and the bonding electrode 13 is electrically connected to the transistor 9 and the light emitting diode 4 respectively. Alternatively, referring to FIG. 2, the array layer 3 includes at least two combined film layers 11, the at least two combined film layers 11 include a first combined film layer 19 and a second combined film layer 20, and the first combined film layer 19 is located on a side of the second combined film layer 20 away from the substrate 2. The first metal layer 12 on the side of the second combined film layer 20 facing away from the substrate 2 may include structures such as an auxiliary connection portion 14 and a first signal line 15 (such as a power line), and the first metal layer 12 on the side of the first combined film layer 19 facing away from the substrate 2 may include a bonding electrode 13.

When a metal film layer needs to be formed on the organic sublayer 6, if the metal film layer is provided between the organic sublayer 6 and the inorganic layer 7 of the combined film layer 11, when the metal film layer is formed, the organic sublayer 6 is exposed, so that water and oxygen in the process can permeate into the organic sublayer 6 and remain inside the array layer 3. However, in the embodiment of the present disclosure, the metal film layer is provided above the integral combined film layer 11, and after the organic sublayer 6 is formed, the inorganic layer 7 is formed first, and then the metal film layer is formed, so that when the metal film layer is formed, the surface of the organic sublayer 6 is covered by the inorganic layer 7, which can reduce water and oxygen permeating into the organic sublayer 6.

In a feasible implementation, as shown in FIG. 3, FIG. 3 is still another schematic structural diagram of a display panel according to an embodiment of the present disclosure, the array layer 3 includes at least one combined film layer 11, the combined film layer 11 includes an organic sublayer 6 and an inorganic layer 7 adjacent to each other, and the inorganic layer 7 in the combined film layer 11 is located on a side of the organic sublayer 6 away from the substrate 2.

In at least part of the combined film layer 11, the organic sublayer 6 includes an aperture 50, and the inorganic layer 7 is further located at least on a side wall of the aperture 50, so as to cut off a transmission path of water and oxygen in the horizontal direction y (parallel to a plane where the substrate 2 is located). Exemplarily, if part of the water and oxygen permeates into the organic sublayer 6 through the side surface of the display panel, the water and oxygen will be blocked by the inorganic layer 7 at the side wall of the aperture 50 when the water and oxygen in organic sublayer 6 laterally transmitted to the aperture 50, and cannot be further transmitted toward the middle display area.

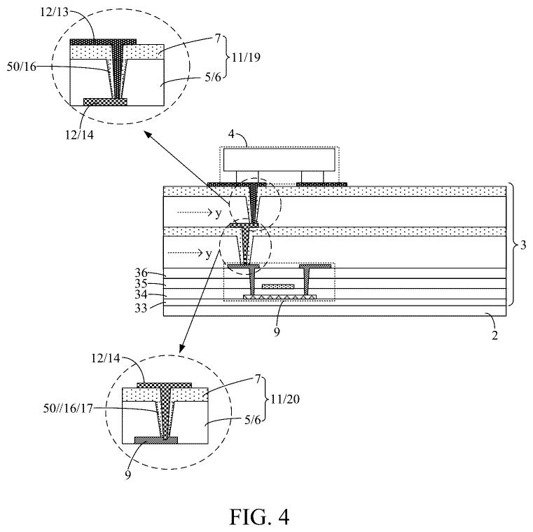

In a feasible implementation, as shown in FIG. 4, FIG. 4 is still another schematic structural diagram of a display panel according to an embodiment of the present disclosure, the aperture 50 includes a connection via hole 16, and the inorganic layer 7 is further located at a hole wall of the connection via hole 16.

The connection via hole 16 may be a via hole connected to any metal structure in the display panel, for example, a via connected between the transistor 9 and the auxiliary connection electrode 14 in the display area, a via connected between the bonding electrode 13 and the auxiliary connection electrode 14, or a via hole connected between the peripheral circuit and the signal line in the frame area.

In this structure, the connection via hole 16 and the aperture 50 which play a connection role in the array layer 3 are reused, on one hand, the punching process can be saved, the process is simplified, and on the other hand, the additional space occupied by the aperture 50 can be avoided, which is particularly suitable for panel structures with high pixel density and complex wiring in the array layer 3. Moreover, the connection via hole 16 in the array layer 3 is generally a high-risk position where water and oxygen are easily invaded across layers, the connection via hole 16 and the aperture 50 are reused, so that the inorganic layer 7 can be specifically set to cover the hole wall of the connection via hole 16, and the connection via hole 16 is subjected to water and oxygen protection, thereby reducing the risk of water and oxygen cross-layer invasion.

Further, referring to FIG. 4 again, the array layer 3 includes a transistor 9, the connection via 16 includes a first connection via hole 17 that expose at least part of the transistor 9, and the inorganic layer 7 is further located on a wall of the first connection via hole 17. At this time, the inorganic layer 7 at the hole wall of the first connection via hole 17 not only can block the lateral transmission of water and oxygen in the organic sublayer 6, but also can block the water and oxygen cross-layer invading into the transistor 9 along the first connection via hole 17, thereby enhancing the water and oxygen protection ability of the transistor 9 and avoiding the functional failure of the transistor device.

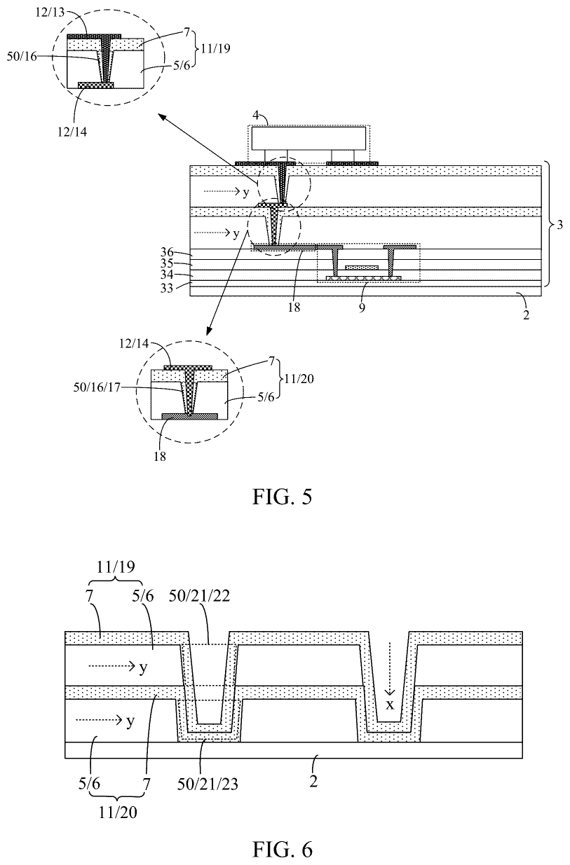

Further, FIG. 5 is another schematic structural diagram of a display panel according to an embodiment of the present disclosure, the array layer 3 includes a transistor 9, the connection via hole 16 does not overlap with the transistor 9 in a direction perpendicular to a plane where the substrate 2 is located. Exemplarily, the auxiliary connection portion 14 may be electrically connected to the connection wire 18 through the first connection via hole 17, and the connection wire 18 is further connected to the transistor 9, so that the first connection via hole 17 does not overlap with the transistor 9.

In this way, the distance between the connection via hole 16 and the transistor 9 can be increased, and even if part of the water and oxygen continue to penetrate inward through the connection via hole 16, the probability that the water and oxygen permeate into the transistor 9 can be reduced.

In addition, it should also be noted that when the inorganic layer 7 is further located on the hole wall of the connection via 16 and the first metal layer 12 is located on the side of the combination film layer 11 away from the substrate 2, the stress of the inorganic layer 7 may also be relieved by using the first metal layer 12. Taking the auxiliary connection portion 14 in FIG. 4 as an example, the auxiliary connection portion 14 is located on a side of the second combined film layer 20 away from the substrate 2, that is, between the organic sublayer 6 in the first combined film layer 19 and the inorganic layer 7 in the second combined film layer 20, and when the inorganic layer 7 in the first combined film layer 19 extends into the connection via hole 16 between the bonding electrode 13 and the auxiliary connection portion 14, the inorganic layer 7 contacts the auxiliary connection portion 14 at the bottom of the connection via 16, so that the auxiliary connection portion 14 relieves the stress of the inorganic layer 7.

In a feasible implementation, as shown in FIG. 6, FIG. 6 is a schematic structural diagram of a groove 21 according to an embodiment of the present disclosure, the aperture 50 may also include a groove 21, and the inorganic layer 7 is recessed in the groove 21.

In this structure, the organic sublayer 6 is discontinuously provided at the groove 21, and the inorganic layer 7 is recessed in the groove 21 to block the transmission of water and oxygen in the horizontal direction y, for example, to block the transmission of the part of water and oxygen permeated into the organic sublayer 6 from the side surface of the display panel.

Further, referring to FIG. 6 again, the combined film layer 11 includes a first combined film layer 19 and a second combined film layer 20, and the first combined film layer 19 is located on a side of the second combined film layer 20 away from the substrate 2. The groove 21 includes a first groove 22 and a second groove 23, the first groove 21 penetrates through the organic sublayer 6 in the first combined film layer 19, and the second groove 23 is located in the organic sublayer 6 in the second combined film layer 20. The first groove 22 overlaps with the second groove 23 in a direction perpendicular to the plane where the substrate 2 is located. That is, the inorganic layer 7 in the second combined film layer 20 is recessed in the second groove 23, and the inorganic layer 7 in the first combined film layer 19 is recessed in the first groove 22 and the second groove 23. In the second combined film layer 20, the second groove 23 may penetrate through the organic sublayer 6 or may not penetrate through the organic sublayer 6, the accompanying drawing of an embodiment of the present disclosure is schematically illustrated with the second groove 23 penetrating through the organic sublayer 6.

With reference to FIG. 6 to FIG. 9, the first groove 22 overlaps with the second groove 23, and the inorganic layer 7 recessed in the first groove 22 is further recessed in the second groove 23, so that the contact area between the two inorganic layers 7 can be increased, for example, the two inorganic layers 7 will increase the water and oxygen block ability in the vertical direction x and/or horizontal direction y where they meet at the bottom and sidewalls of the second trench 23.

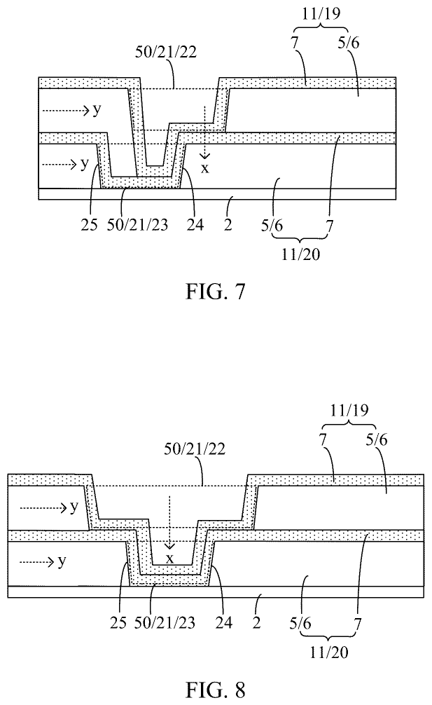

When the first groove 22 and the second groove 23 overlap, in a feasible implementation, as shown in FIG. 7, FIG. 7 is another schematic structural diagram of a groove 21 according to an embodiment of the present disclosure, the second groove 23 includes a first side wall 24 and a second side wall 25 that are opposite to each other, and the first groove 22 at least covers the first side wall 24 in a direction perpendicular to a plane where the substrate 2 is located.

In this arrangement, the two inorganic layers 7 are at least in contact and stacked at the first side wall 24 of the second groove 23, and the inorganic layer 7 at the first side wall 24 has a larger overall thickness, which can cut off the transmission of water and oxygen in the horizontal direction y more effectively.

Further, as shown in FIG. 8, FIG. 8 is another schematic structural diagram of a groove 21 according to an embodiment of the present disclosure, and the first groove 22 further covers the second side wall 25 in a direction perpendicular to a plane where the substrate 2 is located.

That is, the first groove 22 covers the second groove 23, at this time, the two inorganic layers 7 at least contact and stack at the first side wall 22 and the second side wall 25, and even contact and stack at the upper surface of the organic sublayer 6 in the second combined film layer 20, the contact area of the two inorganic layers 7 is larger, and the water and oxygen block ability in the horizontal direction y and the vertical direction x is better.

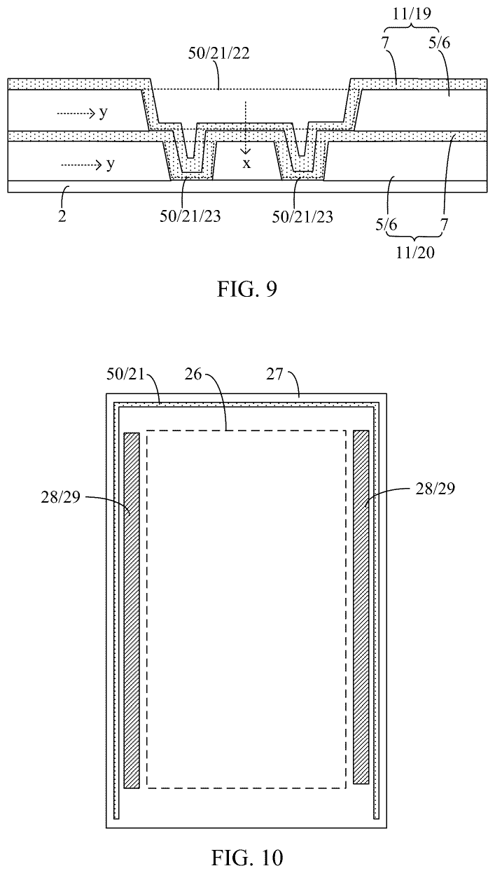

When the first groove 22 and the second groove 23 overlap, in another feasible implementation, in order to increase the contact area of the two inorganic layers 7 to a greater extent and optimize the block effect on water and oxygen, as shown in FIG. 9, which is another schematic structural diagram of the groove 21 provided by the embodiment of the present disclosure, the first groove 22 overlaps with the at least two second grooves 23 in a direction perpendicular to the plane where the substrate 2 is located, that is, a larger groove width is designed for the first groove 22.

In a feasible implementation, as shown in FIG. 10, which is a top view of a display panel according to an embodiment of the present disclosure, the display panel includes a display area 26 and a frame area 27, and a groove 21 is located in the frame area 27.

Since the frame region 27 is not used for image display, the metal circuit is relatively simple, and by providing the above groove 21 in the frame region 27, the design flexibility of the groove 21 can be increased, for example, the extending path of the groove 21 can be increased to further enhance the block effect on water and oxygen. Moreover, when the groove 21 is located in the frame region 27, the groove 21 is closer to the cutting edge of the display panel, and when water and oxygen permeate into the organic sublayer 6 through the side surface of the display panel, the water and oxygen may be blocked by the inorganic layer 7 provided in the groove 21 to prevent the water and oxygen from further permeating into the display region 26.

In a feasible implementation, referring to FIG. 10 again, the frame region 27 includes a peripheral circuit 28, and the groove 21 is located on a side of the peripheral circuit 28 away from the display region 26, so as to perform effective water and oxygen protection on a device in the peripheral circuit 28, thereby preventing water and oxygen permeated through a side surface of the display panel from eroding a transistor device in the peripheral circuit 28.

Further, referring to FIG. 10 again, the peripheral circuit 28 includes a shift register circuit 29.

Compared with a peripheral circuit 28 such as an electrostatic protection circuit, the shift register circuit 29 needs to transmit a driving signal to the transistor 9 in the display area 26, thereby controlling normal light emission of the light emitting diode 4. On one hand, the working stability of the shift register circuit 29 has a more significant influence on display, and by providing the groove 21 on the outer side of the shift register circuit 29, it can be ensured that the shift register circuit 29 is not eroded by water and oxygen, and the display reliability is improved to a greater extent; on the other hand, the shift register circuit 29 needs to be electrically connected to the transistor 9 in the display area 26 through wires such as a grid line and a light emitting control signal line, and after the wires are led out from the shift register circuit 29, it needs to extend first in the frame area 27 on the side of the shift register circuit 29 close to the display area 26, and then extend to the interior of the display area 26 to be electrically connected to the transistor 9, so that the wiring on the side of the shift register circuit 29 close to the display area 26 is relatively complex, and by providing the groove 21 on the side of the shift register circuit 29 away from the display area 26, it can also be avoided that the grid line and the light emitting control signal line are short-circuited with other metal structures at the groove 21.

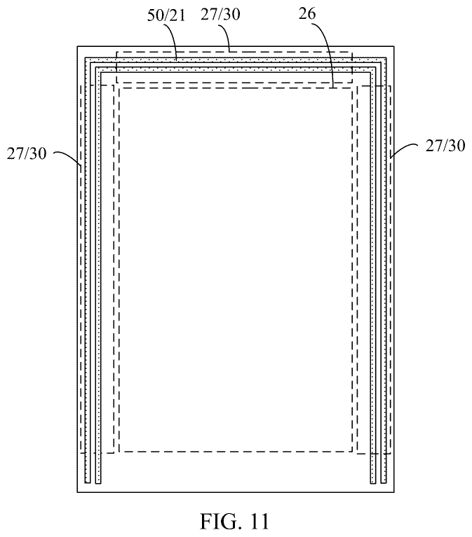

In a feasible implementation, as shown in FIG. 11, FIG. 11 is another top view of the display panel according to an embodiment of the present disclosure, the frame region 27 includes a first frame region 30, and at least two grooves 21 are arranged in the first frame region 30 along a direction from the first frame region 30 to the display region 26, so as to cut off the transmission path of water and oxygen multiple times along the direction from the first frame region 30 to the display region 26.

In a feasible implementation, referring to FIG. 10 and FIG. 11 again, in order to protect the display area 26 in all directions, at least part of the groove 21 surrounds the display area 26 in the frame area 27. It should be noted that since the lower frame wiring is complex and the driving chip may need to be bound, the groove 21 may surround the display area 26 only on the upper frame and the left and right frames.

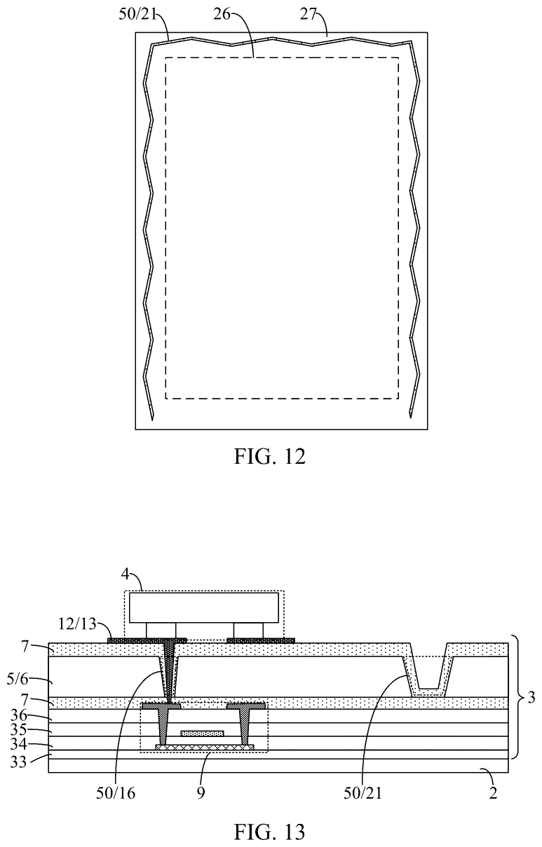

In a feasible implementation, referring to FIG. 10 and FIG. 11 again, at least part of the groove 21 extends in straight line, or, as shown in FIG. 12, FIG. 12 is another top view of the display panel according to the embodiment of the present disclosure, and at least part of the groove 21 may also extend in a wavy line or a broken line to increase the extension length of the groove 21.

It should be noted that the groove 21 extends in a straight line, a wavy line or a broken line, meaning that at least part of the orthographic projection of the groove 21 extends in a straight line, a wavy line or a broken line in the direction perpendicular to the plane where the substrate 2 is located. Taking extension in straight line as an example, in one structure, the groove 21 is located on one side of the display area 26, and the entire groove 21 extends in straight line, or, in another structure, referring to FIG. 10, the groove 21 may also surround the display area 26, at this time, the groove 21 provided in the upper frame, the left frame and the right frame extend in a straight line, respectively.

In a feasible implementation, as shown in FIG. 13, FIG. 13 is another schematic structural diagram of a display panel according to an embodiment of the present disclosure, inorganic layers 7 are respectively provided on two opposite sides of at least one organic sublayer 6, so that the two inorganic layers 7 are used to cut off water and oxygen transmission paths on upper and lower sides of the organic sublayer 6 respectively, and the array layer 3 has better water and oxygen resistance.

Further, referring to FIG. 13 again, the inorganic layers 7 on opposite sides of the organic sublayer 6 are partially contacted. For example, the inorganic layer 7 on the side of the organic sublayer 6 away from the substrate 2 may be in contact with the inorganic layer 7 on the side of the organic sublayer 6 close to the substrate 2 through the aperture 50 (connecting the via hole 16 and/or the groove 21) provided in the organic sublayer 6, thereby realizing stacking of the two inorganic layers 7 at the contact position, and achieving a better water and oxygen block effect.

Taking the organic sublayer 6 located between the bonding electrode 13 and the transistor 9 as an example, when the inorganic layer 7 on the organic sublayer 6 extends into the connection via hole 16 between the bonding electrode 13 and the transistor 9, the inorganic layer 7 under the organic sublayer 6 will be in contact with the bottom of the connection via hole 16, so as to form a stack with the inorganic layer 7 under, so as to block water and oxygen to a greater extent at the connection via hole 16.

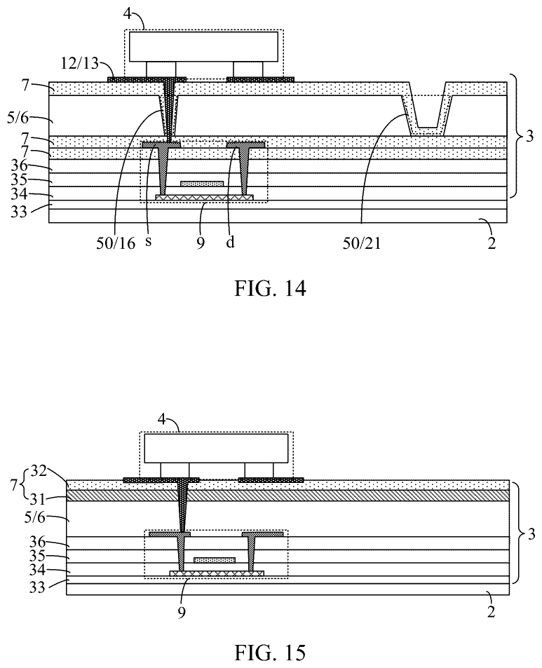

Further, the array layer 3 further includes a metal layer, and two opposite sides of at least one metal layer are respectively provided with an inorganic layer 7. Exemplarily, as shown in FIG. 14, FIG. 14 is another schematic structural diagram of a display panel according to an embodiment of the present disclosure, two opposite sides of a metal layer where a first electrode s and a second electrode d of a transistor 6 are located are respectively provided with an inorganic layer 7, at this time, the metal layer has a large contact area between the two inorganic layers 7 as well as between the two inorganic layers, which can be utilized both to relieve the stress of the inorganic layer 7 and to improve the water oxygen block effect by utilizing the stacked inorganic layers 7.

In a feasible implementation, referring to FIG. 2 again, the array layer 3 includes at least two organic sublayers 6 and at least two inorganic layers 7, and the at least two organic sublayers 6 and the at least two inorganic layers 7 are alternately arranged in sequence, so that the at least two inorganic layers 7 are used to cut off the transmission path of water and oxygen multiple times at different positions, thereby improving the water and oxygen resistance of the array layer 3 more obviously.

Further, referring to FIG. 2 again, a maximum distance between the substrate 2 and the inorganic layer 7 farthest therefrom is a first distance d1, and the first distance d1 is greater than a maximum distance between any one of the organic sublayers 6 and the substrate 2. That is, the inorganic layer 7 is still covered above the organic sublayer 6 farthest from the substrate 2, and the inorganic layer 7 is blocked when the water and oxygen permeate into the array layer 3, thereby reducing the probability of the water and oxygen permeating into the array layer 3 to a greater extent.

In a feasible embodiment, referring again to FIG. 1, the film thickness of the inorganic layer 7 is d, 50 nm≤d≤500 nm, and the inorganic layer 7 has better water and oxygen block performance and avoids too much influence on the overall thickness of the module.

In a feasible implementation, as shown in FIG. 15, FIG. 15 is another schematic structural diagram of a display panel according to an embodiment of the present disclosure, the inorganic layer 7 includes a first sub-layer 31 and a second sub-layer 32 that are stacked, and materials of the first sub-layer 31 and the second sub-layer 32 are different, for example, the first sub-layer 31 is made of silicon oxide material and the second sub-layer 32 is made of silicon nitride. When the inorganic layer 7 adopts a laminated design, at least two laminated layers are formed of different inorganic materials, which can reduce the film stress and improve the film stability of the inorganic layer 7.

In addition, the film thicknesses of the first sub-layer 31 and the second sub-layer 32 may be the same or different, which is not limited in the embodiments of the present disclosure.

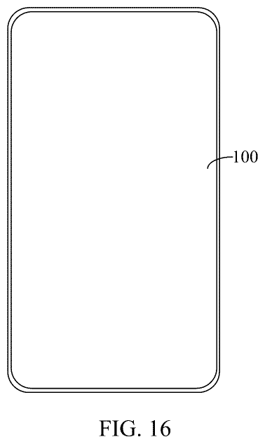

Based on the same inventive concept, an embodiment of the present disclosure further provides a display device, as shown in FIG. 16, FIG. 16 is a schematic structural diagram of a display device according to an embodiment of the present disclosure, and the display device includes the above display panel 100. The specific structure of the display panel 100 has been described in detail in the foregoing embodiments, and details are not described herein again. The display devices shown in FIG. 16 is merely illustrative, and the display devices may be any electronic devices with a display function, such as a mobile phone, a tablet computer, a notebook computer, an electronic paper book, or a television.

The above description is only a preferred embodiment of the present disclosure and is not intended to limit the present disclosure, and any modifications, equivalent substitutions, improvements and the like made within the spirit and principle of the present disclosure should be included within the scope of the present disclosure.

Finally, it should be noted that: The above embodiments are only used to illustrate the technical solutions of the present disclosure, but not to limit the same; although the present disclosure has been described in detail with reference to the above embodiments, those skilled in the art should understand that: The technical solutions described in the above embodiments may still be modified, or some or all of the technical features may be equivalently replaced; and these modifications or substitutions do not make the essence of the corresponding technical solutions depart from the scope of the technical solutions in the embodiments of the present disclosure.

What is claimed is:

1. A display panel, comprising:
a substrate and an array layer located on a side of the substrate; and
a light emitting diode located on a side of the array layer;
wherein, the array layer comprises an organic layer, the organic layer comprises an organic sublayer;
wherein an inorganic layer is arranged on a side of the organic layer away from the substrate.

2. The display panel according to claim 1, wherein:
the array layer comprises a transistor, and the organic sublayer is located on a side of the transistor away from the substrate.

3. The display panel according to claim 2, wherein:
the organic sublayer is a planarization layer.

4. The display panel according to claim 1, wherein:
the array layer comprises at least one combined film layer, the combined film layer comprises the organic sublayer and the inorganic layer that are adjacent to each other, and the inorganic layer is located on a side of the organic sublayer away from the substrate;
wherein, at least part of the at least one combined film layer is provided with a first metal layer on a side of the combined film layer away from the substrate.

5. The display panel according to claim 1, wherein:
the array layer comprises at least one combined film layer, the combined film layer comprises the organic sublayer and the inorganic layer that are adjacent to each other, and the inorganic layer is located on a side of the organic sublayer away from the substrate;
wherein, in at least part of the at least one combined film layer, the organic sublayer comprises an aperture, and the inorganic layer is further at least located on a side wall of the aperture.

6. The display panel according to claim 5, wherein:
the aperture comprises a connection via hole, and the inorganic layer is further located on a wall of the connection via hole.

7. The display panel according to claim 6, wherein:
the array layer comprises a transistor, the connection via hole comprises a first connection via hole corresponding to the transistor, and
the inorganic layer is further located on a wall of the first connection via hole.

8. The display panel according to claim 6, wherein:
the array layer comprises a transistor, and the connection via hole does not overlap with the transistor in a direction perpendicular to a plane of the substrate.

9. The display panel according to claim 5, wherein:
the aperture comprises a groove, and the inorganic layer is recessed in the groove.

10. The display panel according to claim 9, wherein:
the at least one combined film layer comprises a first combined film layer and a second combined film layer, and the first combined film layer is located on a side of the second combined film layer away from the substrate;
the groove comprises a first groove and a second groove, the first groove penetrates through the organic sublayer in the first combined film layer, the second groove is located in the organic sublayer in the second combined film layer, and
in a direction perpendicular to the plane of the substrate, the first groove overlaps with the second groove.

11. The display panel according to claim 10, wherein:
the second groove comprises a first side wall and a second side wall opposite to each other, and the first groove at least covers the first side wall in the direction perpendicular to the plane of the substrate.

12. The display panel according to claim 11, wherein:
the first groove further covers the second side wall in the direction perpendicular to the plane of the substrate.

13. The display panel according to claim 10, wherein:
the first groove overlaps with at least two second grooves in the direction perpendicular to the plane of the substrate.

14. The display panel according to claim 9, wherein:
the display panel comprises a display area and a frame area, and the groove is located in the frame area.

15. The display panel according to claim 14, wherein:
the frame area is provided with a peripheral circuit, and the groove is located on a side of the peripheral circuit away from the display area.

16. The display panel according to claim 15, wherein:
the peripheral circuit comprises a shift register circuit.

17. The display panel according to claim 14, wherein:
the frame area comprises a first frame area, and at least two grooves are arranged in the first frame area in a direction from the first frame area towards the display area.

18. The display panel according to claim 14, wherein:
at least part of the groove surrounds the display area in the frame area.

19. The display panel according to claim 14, wherein:
at least part of the groove extends in a straight line, a wavy line or a broken line.

20. The display panel according to claim 1, wherein:
each of two opposite sides of at least one organic sublayer is respectively provided with the inorganic layer.

21. The display panel according to claim 20, wherein:
inorganic layers on opposite sides of the organic sublayer are partially in contact with each other.

22. The display panel according to claim 1, wherein:
the array layer includes at least two organic sublayers and at least two inorganic layers, and the at least two organic sublayers and the at least two inorganic layers are alternately arranged in sequence.

23. The display panel according to claim 22, wherein:
a maximum distance between the substrate and the inorganic layer that is farthest away from the substrate is defined as a first distance, and the first distance is greater than a maximum distance between each organic sublayer and the substrate.

24. The display panel according to claim 1, wherein:
the inorganic layer has a film thickness of d, where 50 nm≤d≤500 nm.

25. The display panel according to claim 1, wherein:
the inorganic layer comprises a first sub-layer and a second sub-layer that are stacked, and a material of the first sub-layer is different from a material of the second sub-layer.

26. A display device, comprising a display panel, wherein the display panel comprises:
a substrate and an array layer located on a side of the substrate; and
a light emitting diode located on a side of the array layer;
wherein, the array layer comprises an organic layer, the organic layer comprises an organic sublayer, and an inorganic layer is arranged on a side of the organic sublayer away from the substrate.
